(19) United States
(12) Patent Application Publication
(10) Pub. No.: US 2026/0182008 A1
(43) Pub. Date: Jun. 25, 2026

(54) INSULATED GATE BIPOLAR JUNCTION TRANSISTOR (IGBJT)

(71) Applicant: TEXAS INSTRUMENTS INCORPORATED, Dallas, TX (US)

(72) Inventors: Kranthi Karmel Nagothu, Bangalore (IN); Antonio Gallerano, Sachse, TX (US); Yang Xiu, Plano, TX (US); Rajkumar Sankaralingam, Plano, TX (US); Zaichen Chen, Dallas, TX (US)

(21) Appl. No.: 18/987,602

(22) Filed: Dec. 19, 2024

(51) Int. Cl. H10D 84/83; H01L 21/762; H10D 12/00; H10D 12/01; H10D 84/01; H10D 89/60

(52) U.S. Cl. CPC H10D 84/83138; H10D 12/031; H10D 12/411; H10D 84/0151; H10D 84/0156; H10D 84/8314; H10D 89/611; H10W 10/0124; H10W 10/014; H10W 10/13; H10W 10/17; H10W 10/0145

(57) ABSTRACT

The present disclosure generally relates to an insulated gate bipolar junction transistor (IGBJT). In an example, a semiconductor device includes a semiconductor substrate, a first well in the semiconductor substrate, a second well in the semiconductor substrate, a gate electrode over the semiconductor substrate, a source region in the second well, a collector region in the second well, an emitter region in the first well, a drain region in the first well, and a silicide on the source region and the collector region. The first well, source region, and drain region are doped with a first conductivity type. The second well, collector region, and emitter region are doped with a second conductivity type opposite from the first conductivity type. The gate electrode extends laterally over the first well and the second well. The gate electrode is laterally between the source region and the emitter region.

### BACKGROUND

An electrostatic discharge (ESD) event can occur when one object accumulates a static charge and comes into close proximity to or contact with another object with a different charge (which may be a small charge or no charge). The higher accumulated charge from one object is discharged to the object with the lower charge. The initial difference between the charges of the objects can be large, which can result in a large flow of current as a result of the discharge. In electronic devices, the generally sudden and large flow of current resulting from an ESD event can damage electrical components. For this reason, an ESD protection circuit may be included in an electronic device, such as an integrated circuit, to dissipate the charge and divert the flow of current away from electrical components that could otherwise be damaged by an ESD event. Different techniques and devices have been implemented for ESD protection.

### SUMMARY

An example described herein is a semiconductor device. The semiconductor device includes a semiconductor substrate, a first well in the semiconductor substrate, a second well in the semiconductor substrate, a gate electrode over the semiconductor substrate, a source region in the second well, a collector region in the second well, an emitter region in the first well, a drain region in the first well, and a silicide on the source region and the collector region. The first well is doped with a first conductivity type. The second well is doped with a second conductivity type opposite from the first conductivity type. The gate electrode extends laterally over the first well and the second well. The source region is doped with the first conductivity type. The collector region is doped with the second conductivity type. The emitter region is doped with the second conductivity type. The drain region is doped with the first conductivity type. The gate electrode is laterally between the source region and the emitter region.

Another example is a semiconductor device. The semiconductor device includes a semiconductor substrate, a first well in the semiconductor substrate, a second well in the semiconductor substrate, a gate electrode over the semiconductor substrate, a source region in the second well, a collector region in the second well, an isolation structure on the semiconductor substrate and laterally between the source region and the collector region, an emitter region in the first well, and a drain region in the first well. The first well is doped with a first conductivity type. The second well is doped with a second conductivity type opposite from the first conductivity type. The gate electrode extends laterally over the first well and the second well. The source region is doped with the first conductivity type. The source region forms a p-n junction with the second well. The p-n junction is at a first depth from an upper surface of the semiconductor substrate. The collector region is doped with the second conductivity type. A bottom surface of the isolation structure is at a second depth from the upper surface of the semiconductor substrate. The first depth is at least 130% of the second depth. The emitter region is doped with the second conductivity type. The drain region is doped with the first conductivity type. The gate electrode is laterally between the source region and the emitter region.

A further example is a semiconductor device. The semiconductor device includes a semiconductor substrate, a first well in the semiconductor substrate, a second well in the semiconductor substrate, a first gate electrode over the semiconductor substrate, a source region in the second well, a collector region in the second well, a second gate electrode over the semiconductor substrate, an emitter region in the first well, and a drain region in the first well. The first well is doped with a first conductivity type. The second well is doped with a second conductivity type opposite from the first conductivity type. The first gate electrode extends laterally over the first well and the second well. The source region is doped with the first conductivity type. The collector region is doped with the second conductivity type. The second gate electrode is laterally between the source region and the collector region. The emitter region is doped with the second conductivity type. The drain region is doped with the first conductivity type. The first gate electrode is laterally between the source region and the emitter region.

Another example is a semiconductor device. The semiconductor device includes a semiconductor substrate, a first well in the semiconductor substrate, a second well in the semiconductor substrate, a gate electrode over the semiconductor substrate, a source region in the second well, a collector region in the second well, an emitter region in the first well, and a drain region in the first well. The first well is doped with a first conductivity type. The second well is doped with a second conductivity type opposite from the first conductivity type. The gate electrode extends laterally over the first well and the second well. The first well includes a surface portion at an upper surface of the semiconductor substrate. The surface portion of the first well is below the gate electrode and over a bulge portion of the second well. The source region is doped with the first conductivity type. The collector region is doped with the second conductivity type. The emitter region is doped with the second conductivity type. The drain region is doped with the first conductivity type. The gate electrode is laterally between the source region and the emitter region.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a cross-sectional view of a semiconductor device according to some examples.

FIG. 2 is a cross-sectional view of a semiconductor device according to some examples.

FIG. 3 is a cross-sectional view of a semiconductor device according to some examples.

FIG. 4 is a cross-sectional view of a semiconductor device according to some examples.

FIG. 5 is a cross-sectional view of a semiconductor device according to some examples.

FIGS. 6 through 15 are cross-sectional views of the semiconductor device of FIG. 1 at various stages of manufacturing according to an example method.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to an insulated gate bipolar junction transistor (IGBJT), although aspects described herein may apply to other devices. In some examples, a semiconductor device includes a first well and a second well in a semiconductor substrate. The first well is doped with a first conductivity type, and the second well is doped with a second conductivity type opposite from the first conductivity type. An emitter region and a drain region are in the first well, and a source region and a collector region are in the second well. The source region and the drain region are doped with the first conductivity type, and the emitter region and the collector region are doped with the second conductivity type. A gate electrode is over the semiconductor substrate and extends laterally over the first well and the second well and between the source region and the emitter region. In some examples, a silicide is on the source region and the collector region (e.g., extending across an interface between the source and collector regions). In some examples, an isolation structure is on the semiconductor substrate laterally between the source region and the collector region, and the source region forms a p-n junction with the second well. A depth of the p-n junction from an upper surface of the semiconductor substrate is at least 130% of a depth of a bottom surface of the isolation structure from the upper surface of the semiconductor substrate. In some examples, another gate electrode is over the semiconductor substrate laterally between the source region and the collector region. In some examples, the first well includes a surface portion at an upper surface of the semiconductor substrate, and the surface portion of the first well is below the gate electrode and over a bulge portion of the second well.

Example semiconductor devices described herein may be implemented for electrostatic discharge (ESD) protection on an integrated circuit (IC). Some examples may achieve reduced area on the IC and higher drive currents relative to other ESD protection techniques, such as ones that include laterally diffused metal-oxide-semiconductor (LDMOS) or drain extended metal-oxide-semiconductor (DeNMOS) devices. Some examples described herein may achieve improved current capability during ESD event without destroying the device. Some examples may achieve improved safe operating area (SOA) for a given half pitch. Some examples may achieve higher temperature SOA robustness. Other benefits and advantages can be achieved.

Various examples are described subsequently. Although the specific examples may illustrate various aspects of the above generally described features, examples may incorporate any combination of the above generally described features (which are described in more detail in examples below).

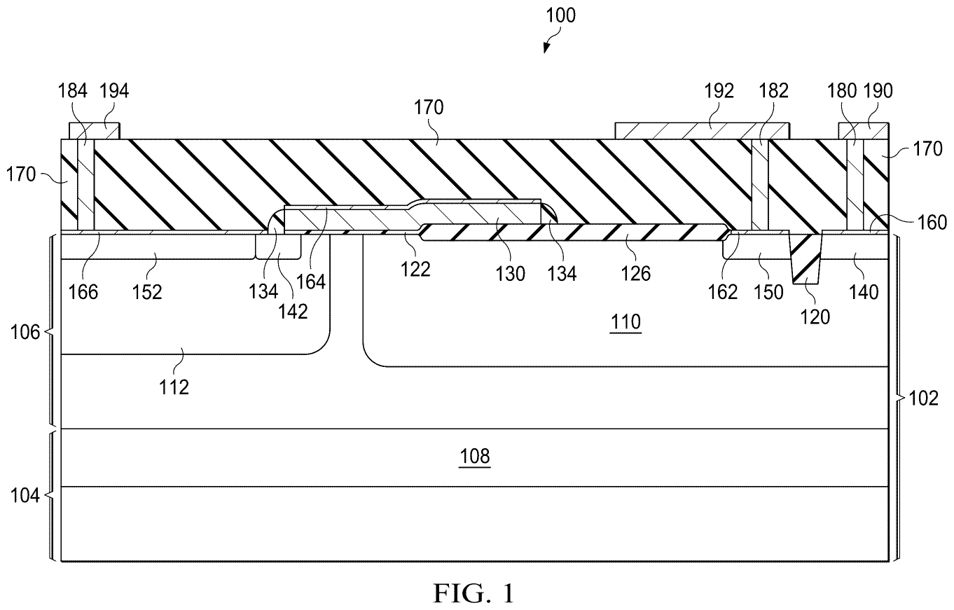

FIGS. 1, 2, 3, 4, and 5 are cross-sectional views of respective semiconductor devices 100, 200, 300, 400, 500 according to some examples. The semiconductor devices 100, 200, 300, 400, 500 include common components, where a same component in FIGS. 1, 2, 3, 4, and 5 are referenced by a same reference number. Such components are described once to avoid unnecessary repetition.

FIGS. 1, 2, 3, 4, and 5 show a semiconductor substrate 102. The semiconductor substrate 102, in the illustrated examples, includes a semiconductor support (or handle) substrate 104 (or handle wafer) and an epitaxial layer 106. The semiconductor support substrate 104 may be a bulk semiconductor substrate, a semiconductor-on-insulator (SOI) substrate, or any other appropriate substrate. The epitaxial layer 106 is epitaxially grown on or over the semiconductor support substrate 104. The epitaxial layer 106 may be or include silicon (Si), silicon germanium (SiGe), gallium arsenide (GaAs), gallium nitride (GaN), the like, or a combination thereof. In some examples, the semiconductor support substrate 104 is or includes a silicon substrate (which may be singulated from a bulk silicon wafer at the conclusion of semiconductor processing), and the epitaxial layer 106 is or includes a layer of silicon. In some examples, the epitaxial layer 106 may be omitted, and a semiconductor material of the semiconductor substrate 102 (e.g., in or on which devices are formed) may be or include silicon (Si), silicon germanium (SiGe), gallium arsenide (GaAs), the like, or a combination thereof. The semiconductor substrate 102 has a top major surface in and/or on which devices (e.g., diodes, transistors, etc.) are generally disposed and formed. In some examples, the epitaxial layer 106 may be p-doped in situ with a p-type dopant (e.g., boron) at a concentration in a range from about 1×10¹⁴ cm⁻³ to about 5×10¹⁵ cm⁻³.

A buried layer 108 (e.g., a doped buried layer) is in the semiconductor substrate 102 (e.g., in the semiconductor support substrate 104). The buried layer 108 is doped with a dopant having a conductivity type opposite from the conductivity type of the dopant of the epitaxial layer 106. A concentration of the dopant of the buried layer 108 is greater than a concentration of the dopant of the epitaxial layer 106. In some examples, the buried layer 108 may be an n-type layer doped with an n-type dopant (e.g., phosphorous and/or arsenic) at a concentration in a range from about 1×10¹⁷ cm⁻³ to about 8×10¹⁸ cm⁻³.

Referring to FIGS. 1, 2, 3, and 5, a first well 110 and a second well 112 are in the semiconductor substrate 102 (e.g., in the epitaxial layer 106). The first well 110 and second well 112 each generally extend from an upper surface of the semiconductor substrate 102 to a depth in the semiconductor substrate 102 (e.g., a depth above the buried layer 108). The first well 110 and second well 112 are laterally separated in FIGS. 1, 2, 3 and 5. In the illustrated examples, the first well 110 is doped with a conductivity type that is opposite from the dopant type of the epitaxial layer 106, and the second well 112 is doped with a conductivity type that is the same as the dopant type of the epitaxial layer 106. A concentration of the dopant of the first well 110 is greater than a concentration of the dopant of the epitaxial layer 106, and a concentration of the dopant of the second well 112 is greater than a concentration of the dopant of the epitaxial layer 106. In some examples, the concentration of the dopant of the first well 110 may be substantially uniform from the upper surface of the semiconductor substrate 102 to a depth in the semiconductor substrate 102 before decreasing to a further depth in the semiconductor substrate 102. In some examples, the concentration of the dopant of the second well 112 may increase from the upper surface of the semiconductor substrate 102 to a depth in the semiconductor substrate 102 before possibly becoming substantially uniform for some depth and then decreasing to a greater depth in the semiconductor substrate 102. In some examples, the first well 110 may be an n-well doped with an n-type dopant at a concentration in a range from about 4×10¹⁵ cm⁻³ to about 7×10¹⁷ cm⁻³, and the second well 112 may be a p-well doped with a p-type dopant at a concentration (e.g., a gradient concentration) in a range from about 8×10¹⁶ cm⁻³ to about 5×10¹⁸ cm⁻³. Other conductivity type dopants and/or concentrations may be implemented in other examples.

Referring to FIGS. 1, 2, 3 and 4, a first isolation structure 120 is in the semiconductor substrate 102 (e.g., the epitaxial layer 106). The first isolation structure 120 extends generally from the upper surface of the semiconductor substrate 102 into a depth in the semiconductor substrate 102. The first isolation structure 120 is also in the first well 110 in the semiconductor substrate 102. In the illustrated examples, the first isolation structure 120 is a shallow trench isolation (STI) structure. The first isolation structure 120 may include a liner layer conformally in a recess (e.g., trench) in the semiconductor substrate 102 and a fill isolation material on the liner layer. For example, the liner layer may be or include an oxide, a nitride, a combination thereof, or the like, and the fill isolation material may be or include an oxide. Other isolation structures may be implemented as the first isolation structure 120.

Referring to FIGS. 1, 2, 3, and 5, a first gate dielectric layer 122 and a second isolation structure 126 are on the semiconductor substrate 102. The first gate dielectric layer 122 is on the upper surface of the semiconductor substrate 102, and the second isolation structure 126 is at the upper surface of the semiconductor substrate 102 and may extend into the semiconductor substrate 102. The first gate dielectric layer 122 extends laterally from the second isolation structure 126. The second isolation structure 126 is over the first well 110, and the first gate dielectric layer 122 extends laterally from the second isolation structure 126 from over the first well 110 to over the second well 112, including over a portion of the semiconductor substrate 102 laterally separating the first well 110 and second well 112. In some examples, the first gate dielectric layer 122 is an oxide (e.g., silicon oxide), although another dielectric material may be implemented as the first gate dielectric layer 122. In the illustrated examples, the second isolation structure 126 is a local oxidation of semiconductor (LOCOS) structure, although in other examples, another isolation structure may be implemented as the second isolation structure 126, such as a STI structure. In some examples, the second isolation structure 126 may be omitted (for example, for a low breakdown voltage application), and the first gate dielectric layer 122 may be on the upper surface of the semiconductor substrate 102 where the second isolation structure 126 is illustrated.

A first gate electrode 130 is over the first gate dielectric layer 122 and the second isolation structure 126. The first gate electrode 130 has a sidewall that generally aligns with a sidewall of the first gate dielectric layer 122, which sidewalls are over the second well 112, and has another sidewall over the second isolation structure 126, which sidewall is over the first well 110. The first gate electrode 130 includes a conductive material. In some examples, the first gate electrode 130 is or includes polycrystalline silicon (polysilicon), such as doped polysilicon. First gate spacers 134 are on respective sidewalls of the first gate electrode 130. The first gate spacers 134 may be or include a dielectric material, such as a nitride, an oxide, a combination thereof, or the like. As illustrated, the second isolation structure 126 is partially under the first gate electrode 130 and extends laterally away from the first gate electrode 130. In examples in which the second isolation structure 126 is omitted, the first gate dielectric layer 122 may underly the first gate electrode 130 and extend laterally away from the first gate electrode 130 similar to what is shown for the second isolation structure 126 in the figures.

Referring to FIGS. 1, 2, and 3, a drain region 140 and an emitter region 150 are in the semiconductor substrate 102 (e.g., the epitaxial layer 106) in the first well 110. The drain region 140 and emitter region 150 extend from the upper surface of the semiconductor substrate 102 to a depth in the semiconductor substrate 102 that is less than the respective depths in the semiconductor substrate 102 to which the first well 110 and the first isolation structure 120 extend. The emitter region 150 is laterally between the first isolation structure 120 and the second isolation structure 126 (or the first gate dielectric layer 122 when the second isolation structure 126 is omitted). The first isolation structure 120 is laterally between the emitter region 150 and the drain region 140. The drain region 140 is doped with a conductivity type that is the same as the conductivity type of the first well 110, and a concentration of the dopant of the drain region 140 is greater than the concentration of the dopant of the first well 110. The emitter region 150 is doped with a conductivity type that is opposite from the conductivity type of the first well 110, and a concentration of the dopant of the emitter region 150 is greater than the concentration of the dopant of the first well 110. In some examples, the drain region 140 may be doped with an n-type dopant at a concentration in a range from about 1×10²⁰ cm⁻³ to about 6×10²⁰ cm⁻³, and the emitter region 150 may be doped with a p-type dopant at a concentration in a range from about 1×10²⁰ cm⁻³ to about 2×10²⁰ cm⁻³. Other conductivity type dopants and/or concentrations may be implemented in other examples.

Metal-semiconductor compound 160, 162 are on the upper surface of the semiconductor substrate 102 at the drain region 140 and emitter region 150, respectively, and metal-semiconductor compound 164 is on an upper surface of the first gate electrode 130 (e.g., in examples where the first gate electrode 130 is or includes polysilicon). The metal-semiconductor compound 160 extends laterally from the first isolation structure 120. The metal-semiconductor compound 162 is laterally between the first isolation structure 120 and the second isolation structure 126 (or the first gate dielectric layer 122 when the second isolation structure 126 is omitted). The metal-semiconductor compound 160, 162, 164 may be a silicide (e.g., NiSix, TiSix, CoSix, PtSix, WSix), a germanicide, or the like.

A dielectric layer 170 is over the semiconductor substrate 102. More specifically, the dielectric layer 170 is over (e.g., on) the metal-semiconductor compound 160, 162, 164, the first isolation structure 120, the second isolation structure 126, and the first gate spacers 134. The dielectric layer 170 may include one or more dielectric sub-layers. For example, the dielectric layer 170 may include a conformal first dielectric sub-layer over the semiconductor substrate 102 and a second dielectric sub-layer over the first dielectric sub-layer. The conformal first dielectric sub-layer may be an etch stop layer, which may be or include silicon nitride, silicon oxynitride, the like, or a combination thereof. The second dielectric sub-layer may be or include silicon oxide, silicon nitride, or the like. The dielectric layer 170 may be or include a pre-metal dielectric (PMD), an inter-layer dielectric (ILD), or the like.

Metal contacts 180, 182 extend through the dielectric layer 170 and contact respective metal-semiconductor compound 160, 162. The metal contacts 180, 182 may each include one or more barrier and/or adhesion layers (e.g., titanium nitride (TiN), tantalum nitride (TaN), the like, or a combination thereof) conformally in a respective opening through the dielectric layer 170, and a fill metal (e.g., tungsten (W), copper (Cu), aluminum (Al), the like, or a combination thereof) over and/or on the barrier and/or adhesion layer(s). Metal lines 190, 192 are over the dielectric layer 170 and over and contacting the metal contacts 180, 182, respectively. The metal lines 190, 192 may each include one or more barrier and/or adhesion layers (e.g., titanium nitride (TiN), tantalum nitride (TaN), the like, or a combination thereof) over the dielectric layer 170, and a fill metal (e.g., tungsten (W), copper (Cu), aluminum (Al), the like, or a combination thereof) over and/or on the barrier and/or adhesion layer(s).

Referring to FIG. 1, a source region 142 and a collector region 152 are in the semiconductor substrate 102 (e.g., the epitaxial layer 106) in the second well 112. The source region 142 and collector region 152 extend from the upper surface of the semiconductor substrate 102 to a depth in the semiconductor substrate 102 that is less than the depth in the semiconductor substrate 102 to which the second well 112 extends. The source region 142 is proximate the first gate electrode 130. As illustrated, a portion of the source region 142 underlies the first gate electrode 130, and another portion of the source region 142 extends laterally away from the first gate electrode 130 and corresponding first gate spacer 134 that overlies the source region 142. The collector region 152 adjoins the source region 142 and extends laterally away from the source region 142 in a direction away from the first gate electrode 130. No isolation structure including an isolation material (e.g., STI structure, LOCOS structure, or the like) is in the semiconductor substrate 102 laterally between the source region 142 and the collector region 152.

The source region 142 is doped with a conductivity type that is opposite from the conductivity type of the second well 112, and a concentration of the dopant of the source region 142 is greater than the concentration of the dopant of the second well 112. The collector region 152 is doped with a conductivity type that is the same as the conductivity type of the second well 112, and a concentration of the dopant of the collector region 152 is greater than the concentration of the dopant of the second well 112. The source region 142 is doped with a conductivity type that is opposite from the conductivity type of the collector region 152, and the source region 142 and collector region 152 form a p-n junction at the upper surface of the semiconductor substrate 102. The collector region 152 may also be or be considered a substrate or body contact region. In some examples, the source region 142 may be doped with an n-type dopant at a concentration in a range from about 1×10²⁰ cm⁻³ to about 6×10²⁰ cm⁻³, and the collector region 152 may be doped with a p-type dopant at a concentration in a range from about 5×10¹⁹ cm⁻³ to about 2×10²⁰ cm⁻³. Other conductivity type dopants and/or concentrations may be implemented in other examples.

Metal-semiconductor compound 166 is on the upper surface of the semiconductor substrate 102 at the source region 142 and collector region 152 together. The metal-semiconductor compound 166 is on both the source region 142 and collector region 152—e.g., across the p-n junction at the upper surface of the semiconductor substrate 102. The metal-semiconductor compound 166 extends laterally from the first gate spacer 134 over the source region 142. The metal-semiconductor compound 166 is like the metal-semiconductor compound 160, 162, 164 (e.g., silicide in some examples). The dielectric layer 170 is further over the metal-semiconductor compound 166. A metal contact 184 extends through the dielectric layer 170 and contacts the metal-semiconductor compound 166. The metal contact 184 is like the metal contacts 180, 182. A metal line 194 is over the dielectric layer 170 and over and contacting the metal contact 184. The metal line 194 is like the metal lines 190, 192.

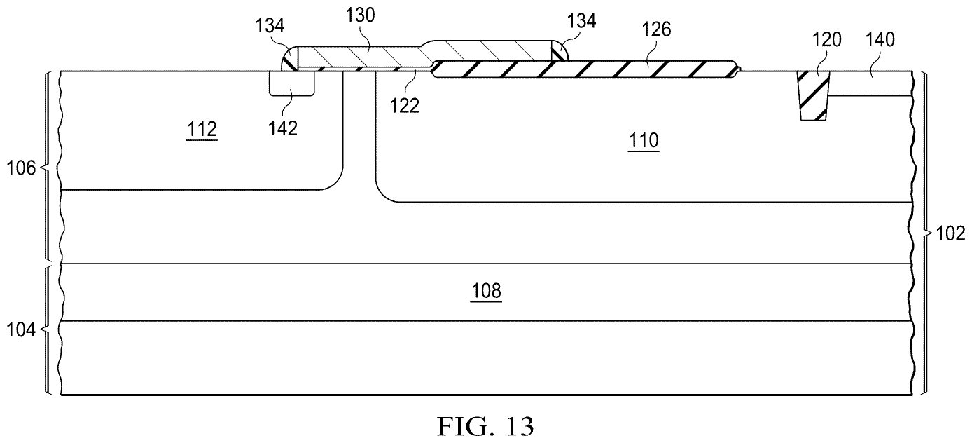

The semiconductor device 100 of FIG. 1 has the source region 142 abutted with the collector region 152 (which may also be a body contact region). As described, the source region 142 and the collector region 152 are shorted together by the metal-semiconductor compound 166 (e.g., silicide), which may result in a maximum achievable SOA at a lowest half pitch. The low resistance between the source region 142 and the collector region 152 (e.g., body contact region) may result in improved SOA over a temperature variation. A higher gate-to-source voltage may be achieved, which may increase and improve a current capability during ESD event without destroying the device. In some instances, minimal diffusion from the source region 142 may be achieved. In some instances, a minimal source/drain enclosure of the first gate electrode 130 (e.g., enclosure of the resist opening on the source side during the source/drain implant as depicted in FIG. 13, the opening extended beyond the source-side edge of the gate electrode) may be implemented. A cumulative area reduction in some ESD protection applications implementing the semiconductor device 100 may be realized. Also, in some ESD protection applications, a diode electrically connected between the source region 142 and the collector region 152 may be omitted.

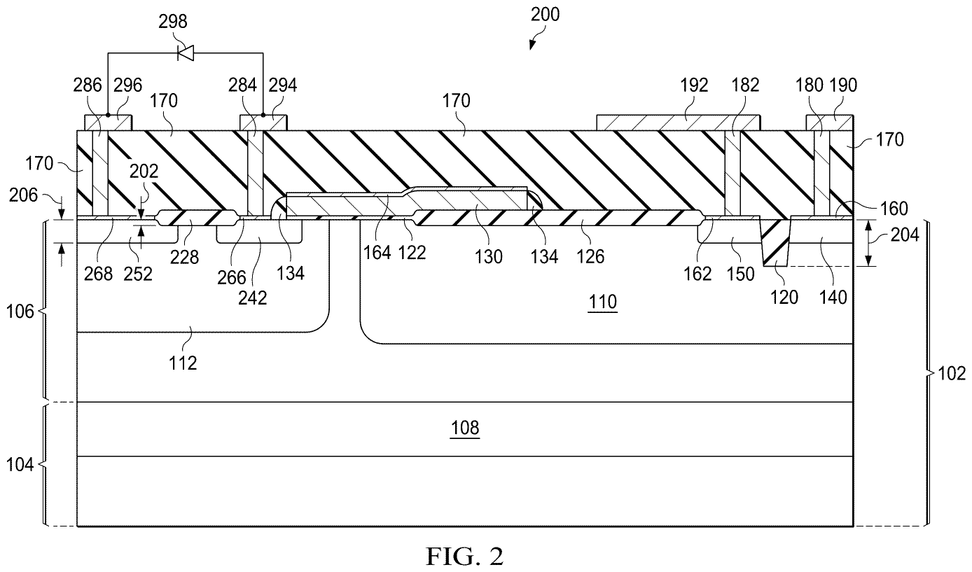

Referring to FIG. 2, a third isolation structure 228 is on the semiconductor substrate 102. The third isolation structure 228 is at the upper surface of the semiconductor substrate 102 and extends into the semiconductor substrate 102 to a depth 202 from the upper surface of the semiconductor substrate 102. The third isolation structure 228 has a bottom surface at the depth 202 from the upper surface of the semiconductor substrate 102. The third isolation structure 228 is over the second well 112. In comparison, the first isolation structure 120 extends into the semiconductor substrate 102 to a depth 204 from the upper surface of the semiconductor substrate 102. The first isolation structure 120 has a bottom surface at the depth 204 from the upper surface of the semiconductor substrate 102. The depth 204 of the first isolation structure 120 is a greater depth than the depth 202 of the third isolation structure 228. In the illustrated examples, the third isolation structure 228 is a LOCOS structure, although in other examples, another isolation structure may be implemented as the third isolation structure 228. In some examples, the third isolation structure 228 may extend less into the semiconductor substrate 102 than the second isolation structure 126.

A source region 242 and a collector region 252 are in the semiconductor substrate 102 (e.g., the epitaxial layer 106) in the second well 112. The source region 242 and collector region 252 extend from the upper surface of the semiconductor substrate 102 to a depth 206 in the semiconductor substrate 102 that is less than the depth in the semiconductor substrate 102 to which the second well 112 extends. The source region 242, in the illustrated example, forms a p-n junction with the second well 112 at the depth 206. Although the source region 242 and the collector region 252 are illustrated to extend to a same depth 206, the source region 242 may extend to a depth different than (e.g., greater or less than) a depth to which the collector region 252 extends. As illustrated, the depth 206 to which the source region 242 extends (and where the p-n junction is formed) is greater than the depth 202 to which the third isolation structure 228 extends. In some examples, the depth 206 to which the source region 242 extends (and where the p-n junction is formed) is at least 130% of the depth 202 to which the third isolation structure 228 extends. Similarly, as illustrated, the depth 206 to which the collector region 252 extends is greater than the depth 202 to which the third isolation structure 228 extends. In some examples, the depth 206 to which the collector region 252 extends is at least 130% of the depth 202 to which the third isolation structure 228 extends.

The source region 242 is proximate the first gate electrode 130. As illustrated, a portion of the source region 242 underlies the first gate electrode 130, and another portion of the source region 242 extends laterally away from the first gate electrode 130 to under the third isolation structure 228. Generally, the source region 242 is laterally between the first gate electrode 130 and the third isolation structure 228, and the third isolation structure 228 is laterally between the source region 242 and the collector region 252. The collector region 252 includes a portion that underlies the third isolation structure 228. The source region 242 and the collector region 252 are laterally separated.

The source region 242 is doped with a conductivity type that is opposite from the conductivity type of the second well 112, and a concentration of the dopant of the source region 242 is greater than the concentration of the dopant of the second well 112. The collector region 252 is doped with a conductivity type that is the same as the conductivity type of the second well 112, and a concentration of the dopant of the collector region 252 is greater than the concentration of the dopant of the second well 112. The source region 242 is doped with a conductivity type that is opposite from the conductivity type of the collector region 252. The collector region 252 may also be or be considered a substrate or body contact region. In some examples, the source region 242 may be doped with an n-type dopant at a concentration in a range from about 1×10²⁰ cm⁻³ to about 6×10²⁰ cm⁻³, and the collector region 252 may be doped with a p-type dopant at a concentration in a range from about 5×10¹⁹ cm⁻³ to about 2×10²⁰ cm⁻³. Other conductivity type dopants and/or concentrations may be implemented in other examples.

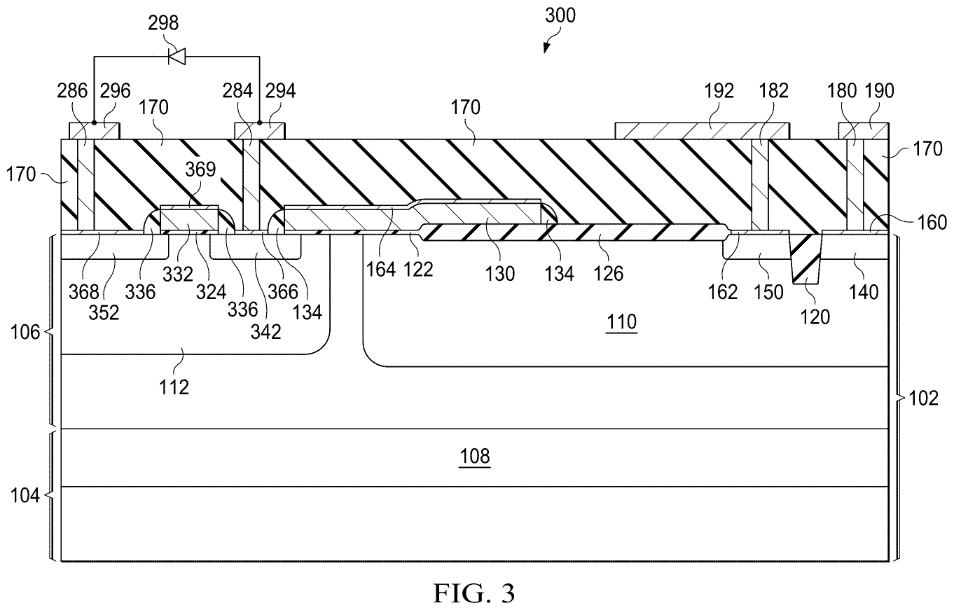

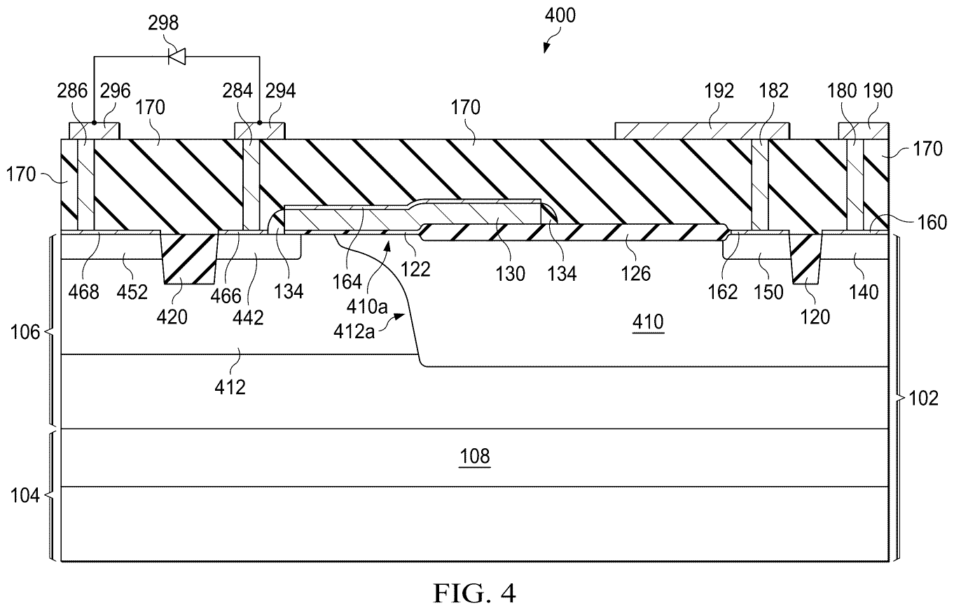

Metal-semiconductor compound 266, 268 are on the upper surface of the semiconductor substrate 102 at the source region 242 and collector region 252, respectively. The metal-semiconductor compound 266 is laterally between the third isolation structure 228 and the first gate spacer 134 over the source region 242. The metal-semiconductor compound 268 extend laterally from the third isolation structure 228. The metal-semiconductor compound 266, 268 are like the metal-semiconductor compound 160, 162, 164. The dielectric layer 170 is further over the metal-semiconductor compound 266, 268 and the third isolation structure 228. Metal contacts 284, 286 extend through the dielectric layer 170 and contact the metal-semiconductor compound 266, 268, respectively. The metal contacts 284, 286 are like the metal contacts 180, 182. Metal lines 294, 296 are over the dielectric layer 170 and over and contacting the metal contacts 284, 286, respectively. The metal lines 294, 296 are like the metal line 194. In some examples, the metal contacts 284, 286 of FIG. 2 (and subsequently in FIGS. 3 and 4) may be electrically connected to an anode terminal and a cathode terminal of a diode 298 in the semiconductor substrate 102, respectively, via metal lines 294, 296. The diode 298 may be omitted in other examples.

The semiconductor device 200 of FIG. 2 may achieve isolation between the source region 242 and the collector region 252 (which may be a body contact region) with reduced source-to-collector (body) distance, which may reduce source-to-collector (body) resistance. A trigger voltage of the semiconductor device 200 may therefore be improved. The SOA of the semiconductor device 200 may be less sensitive to high temperatures resulting in improved SOA robustness. The SOA may be increased without increasing a half pitch.

Referring to FIG. 3, a second gate dielectric layer 324 is on the semiconductor substrate 102. The second gate dielectric layer 324 is on the upper surface of the semiconductor substrate 102. The second gate dielectric layer 324 is over the second well 112. The second gate dielectric layer 324 may be like the first gate dielectric layer 122. A second gate electrode 332 is over the second gate dielectric layer 324. The second gate electrode 332 may be like the first gate electrode 130 (e.g., such as being or including polysilicon, and further, doped polysilicon). Second gate spacers 336 are on respective sidewalls of the second gate electrode 332. The second gate spacers 336 may be like the first gate spacers 134.

A source region 342 and a collector region 352 are in the semiconductor substrate 102 (e.g., the epitaxial layer 106) in the second well 112. The source region 342 and collector region 352 extend from the upper surface of the semiconductor substrate 102 to a depth in the semiconductor substrate 102 that is less than the depth in the semiconductor substrate 102 to which the second well 112 extends. The source region 342 is proximate the first gate electrode 130. As illustrated, a portion of the source region 342 underlies the first gate electrode 130, and another portion of the source region 342 extends laterally away from the first gate electrode 130 to under the second gate dielectric layer 324 and second gate electrode 332. Generally, the source region 342 is laterally between the first gate electrode 130 and the second gate electrode 332, and the second gate electrode 332 is laterally between the source region 342 and the collector region 352. The collector region 352 includes a portion that underlies the second gate electrode 332. The source region 342 and the collector region 352 are laterally separated.

The source region 342 is doped with a conductivity type that is opposite from the conductivity type of the second well 112, and a concentration of the dopant of the source region 342 is greater than the concentration of the dopant of the second well 112. The collector region 352 is doped with a conductivity type that is the same as the conductivity type of the second well 112, and a concentration of the dopant of the collector region 352 is greater than the concentration of the dopant of the second well 112. The source region 342 is doped with a conductivity type that is opposite from the conductivity type of the collector region 352. The collector region 352 may also be or be considered a substrate or body contact region. In some examples, the source region 342 may be doped with an n-type dopant at a concentration in a range from about 1×10²⁰ cm⁻³ to about 6×10²⁰ cm⁻³, and the collector region 352 may be doped with a p-type dopant at a concentration in a range from about 5×10¹⁹ cm⁻³ to about 2×10²⁰ cm⁻³. Other conductivity type dopants and/or concentrations may be implemented in other examples.

Metal-semiconductor compound 366, 368 are on the upper surface of the semiconductor substrate 102 at the source region 342 and collector region 352, respectively, and metal-semiconductor compound 369 is on an upper surface of the second gate electrode 332. The metal-semiconductor compound 366 is laterally between the first gate spacer 134 over the source region 342 and the second gate spacer 336 over the source region 342. The metal-semiconductor compound 368 extends laterally from the second gate spacer 336 over the collector region 352. The metal-semiconductor compound 366, 368, 369 are like the metal-semiconductor compound 160, 162, 164. The dielectric layer 170 is further over the metal-semiconductor compound 366, 368, 369 and the second gate spacers 336. Metal contacts 284, 286 extend through the dielectric layer 170 and contact the metal-semiconductor compound 366, 368, respectively. Metal lines 294, 296 are over the dielectric layer 170 and over and contacting the metal contacts 284, 286, respectively. In some examples, the second gate electrode 332 is electrically connected to the collector region 352, which may further be electrically connected to a ground node. For example, the metal contact 286 and another contact to the second gate electrode 332 (not shown) may contact a same metal line that is on the dielectric layer 170, or the metal contact 286 and another contact to the second gate electrode 332 (not shown) may be electrically connected together through metal via(s) and/or metal lines in metal layers (not shown) over the dielectric layer 170.

The semiconductor device 300 of FIG. 3 may achieve isolation between the source region 342 and the collector region 352 (which may be a body contact region) with reduced source-to-collector (body) distance, which may reduce source-to-collector (body) resistance. A minimum dimension of the second gate electrode 332 in some processes may be less than a minimum dimension of an isolation structure, such as an STI structure or a LOCOS structure. Hence, the second gate electrode 332 may permit a reduced source-to-collector (body) distance. A trigger voltage of the semiconductor device 300 may therefore be improved. The SOA of the semiconductor device 300 may be less sensitive to high temperatures resulting in improved SOA robustness.

Referring to FIG. 4, a first well 410 and a second well 412 are in the semiconductor substrate 102 (e.g., in the epitaxial layer 106). The first well 410 and second well 412 each generally extend from an upper surface of the semiconductor substrate 102 to a depth in the semiconductor substrate 102 (e.g., a depth above the buried layer 108). The first well 410 and second well 412 laterally adjoin in FIG. 4. The first well 410 includes a surface portion 410a, and the second well 412 includes a bulge portion 412a. The surface portion 410a extends from the upper surface of the semiconductor substrate 102 and is over and adjoins the bulge portion 412a. In the illustrated example, the first well 410 is doped with a conductivity type that is opposite from the dopant of the epitaxial layer 106, and the second well 412 is doped with a conductivity type that is the same as the dopant of the epitaxial layer 106. A p-n junction is formed by the first well 410 and the second well 412a (e.g., by the surface portion 410a and the bulge portion 412a).

A concentration of the dopant of the first well 410 is greater than a concentration of the dopant of the epitaxial layer 106, and a concentration of the dopant of the second well 412 is greater than a concentration of the dopant of the epitaxial layer 106. In some examples, the concentration of the dopant of the first well 410 may be substantially uniform from the upper surface of the semiconductor substrate 102 to a depth in the semiconductor substrate 102 before decreasing to a further depth in the semiconductor substrate 102. In some examples, the concentration of the dopant of the second well 412 may increase from the upper surface of the semiconductor substrate 102 to a depth in the semiconductor substrate 102 before possibly becoming substantially uniform for some depth and then decreasing to a greater depth in the semiconductor substrate 102. In some examples, the first well 410 may be an n-well doped with an n-type dopant at a concentration in a range from about 4×10¹⁵ cm⁻³ to about 7×10¹⁷ cm⁻³, and the second well 412 may be a p-well doped with a p-type dopant at a concentration (e.g., a gradient concentration) in a range from about 8×10¹⁶ cm⁻³ to about 5×10¹⁸ cm⁻³. Other conductivity type dopants and/or concentrations may be implemented in other examples.

Like described above, a first isolation structure 120 is in the semiconductor substrate 102 (e.g., the epitaxial layer 106), and more specifically, in the first well 410 in the semiconductor substrate 102. A first gate dielectric layer 122 and a second isolation structure 126 are on the semiconductor substrate 102. The second isolation structure 126 is over the first well 410, and the first gate dielectric layer 122 extends laterally from the second isolation structure 126 from over the first well 410 to over the second well 412. Like above, the second isolation structure 126 may be omitted, and the first gate dielectric layer 122 may extend to where the second isolation structure 126 is omitted. The first gate dielectric layer 122 is over the surface portion 410a and the bulge portion 412a. A first gate electrode 130 is over the first gate dielectric layer 122 and the second isolation structure 126 and is over the surface portion 410a and the bulge portion 412a. First gate spacers 134 are on respective sidewalls of the first gate electrode 130. A drain region 140 and an emitter region 150 are in the semiconductor substrate 102 (e.g., the epitaxial layer 106) in the first well 410. Aspects of these components may be as described above with respect to FIGS. 1, 2, and 3 with the first well 410 replacing the first well 110.

A third isolation structure 420 is in the semiconductor substrate 102 (e.g., the epitaxial layer 106). The third isolation structure 420 extends from the upper surface of the semiconductor substrate 102 into a depth in the semiconductor substrate 102. The third isolation structure 420 is also in the second well 412 in the semiconductor substrate 102. In the illustrated examples, the third isolation structure 420 is an STI structure. Other structures may be implemented as the third isolation structure 420—e.g., the third isolation structure 228, the second gate electrode 332 over the first gate dielectric layer 122. In some examples, the third isolation structure 420 may be omitted, and the source region 442 and the collector region 452 may be abutted together and shorted by a metal-semiconductor compound, like the source region 142, collector region 152, and metal-semiconductor compound 166 as shown in FIG. 1.

A source region 442 and a collector region 452 are in the semiconductor substrate 102 (e.g., the epitaxial layer 106) in the second well 412. The source region 442 and collector region 452 extend from the upper surface of the semiconductor substrate 102 to a depth in the semiconductor substrate 102 that is less than the depth in the semiconductor substrate 102 to which the second well 412 extends. The source region 442 is proximate the first gate electrode 130. As illustrated, a portion of the source region 442 underlies the first gate electrode 130, and another portion of the source region 442 extends laterally away from the first gate electrode 130. Generally, the source region 442 is laterally between the first gate electrode 130 and the third isolation structure 420, and the third isolation structure 420 is laterally between the source region 442 and the collector region 452. In some examples, the source region 442 and collector region 452 extend from the upper surface of the semiconductor substrate 102 to a depth in the semiconductor substrate 102 that is less than the depth in the semiconductor substrate 102 to which the third isolation structure 420 extends. For example, the depth of the source region 442 (and the collector region 452) into the semiconductor substrate 102 may vary between 30% to 45% of the depth of the third isolation structure 420 into the semiconductor substrate 102.

The source region 442 is doped with a conductivity type that is opposite from the conductivity type of the second well 412, and a concentration of the dopant of the source region 442 is greater than the concentration of the dopant of the second well 412. The collector region 452 is doped with a conductivity type that is the same as the conductivity type of the second well 412, and a concentration of the dopant of the collector region 452 is greater than the concentration of the dopant of the second well 412. The source region 442 is doped with a conductivity type that is opposite from the conductivity type of the collector region 452. The collector region 452 may also be or be considered a substrate or body contact region. In some examples, the source region 442 may be doped with an n-type dopant at a concentration in a range from about 1×10²⁰ cm⁻³ to about 6×10²⁰ cm⁻³, and the collector region 452 may be doped with a p-type dopant at a concentration in a range from about 5×10¹⁹ cm⁻³ to about 2×10²⁰ cm⁻³. Other conductivity type dopants and/or concentrations may be implemented in other examples.

Metal-semiconductor compound 160, 162, 466, 468 are on the upper surface of the semiconductor substrate 102 at the drain region 140, emitter region 150, source region 442, and collector region 452, respectively, and metal-semiconductor compound 164 is on an upper surface of the first gate electrode 130. The metal-semiconductor compound 466 is laterally between the third isolation structure 420 and the first gate spacer 134 over the source region 442. The metal-semiconductor compound 468 extend laterally from the third isolation structure 420. The metal-semiconductor compound 466, 468 may be like the metal-semiconductor compound 160, 162. A dielectric layer 170 is over the semiconductor substrate 102. More specifically, the dielectric layer 170 is over (e.g., on) the metal-semiconductor compound 160, 162, 164, 466, 468, the first isolation structure 120, the second isolation structure 126, the third isolation structure 420, and the first gate spacers 134. Metal contacts 180, 182, 284, 286 extend through the dielectric layer 170 and contact respective metal-semiconductor compound 160, 162, 466, 468. Metal lines 190, 192, 294, 296 are over the dielectric layer 170 and over and contacting the metal contacts 180, 182, 284, 286, respectively.

The semiconductor device 400 of FIG. 4 pushes the second well 412 into a channel region (e.g., underlying the first gate electrode 130 and in the semiconductor substrate 102) of the semiconductor device 400. This may increase the maximum allowed trigger voltage. Lowering an internal base resistance of a parasitic NPN of the semiconductor device 400 may increase the trigger voltage. Further, the second well 412 may reduce body resistance, which may increase the SOA without increasing half pitch of the semiconductor device 400.

In some examples, the first well 410 and second well 412 of FIG. 4 may replace the first well 110 and second well 112 in the semiconductor devices 100, 200, 300, 500 of FIGS. 1, 2, 3 and 5.

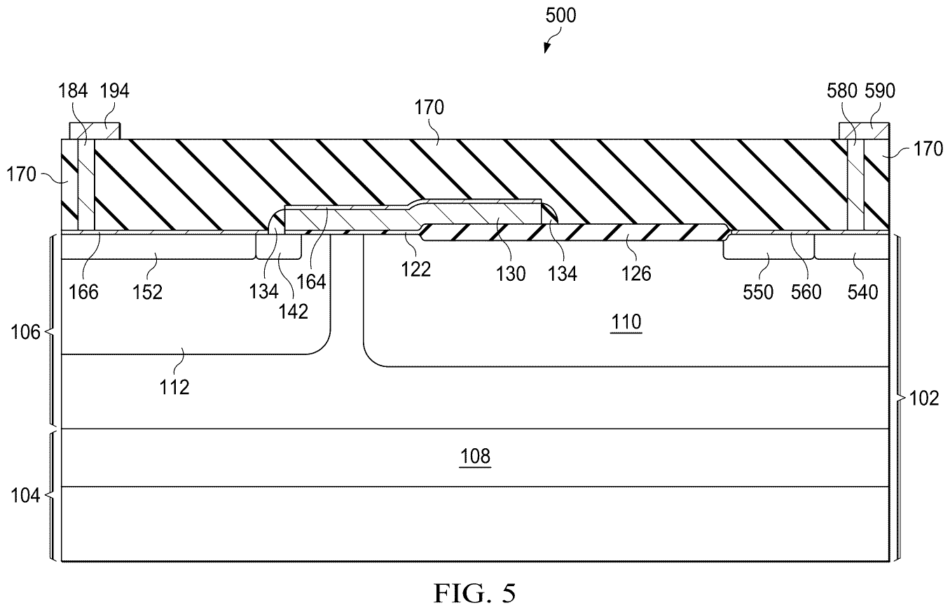

Referring to FIG. 5, a drain region 540 and an emitter region 550 are in the semiconductor substrate 102 (e.g., the epitaxial layer 106) in the first well 110. The drain region 540 and emitter region 550 extend from the upper surface of the semiconductor substrate 102 to a depth in the semiconductor substrate 102 that is less than the respective depths in the semiconductor substrate 102 to which the first well 110 extends. The semiconductor device 500 of FIG. 5 has the drain region 540 abutted with the emitter region 550. The emitter region 550 is laterally between the second isolation structure 126 (or the first gate dielectric layer 122 when the second isolation structure 126 is omitted) and the drain region 540. The drain region 540 adjoins the emitter region 550 and extends laterally away from emitter region 550 in a direction away from the second isolation structure 126 (or the first gate dielectric layer 122 when the second isolation structure 126 is omitted). No isolation structure including an isolation material (e.g., STI structure, LOCOS structure, or the like) is in the semiconductor substrate 102 laterally between the source region 142 and the emitter region 550. The drain region 540 is doped with a conductivity type that is the same as the conductivity type of the first well 110, and a concentration of the dopant of the drain region 540 is greater than the concentration of the dopant of the first well 110. The emitter region 550 is doped with a conductivity type that is opposite from the conductivity type of the first well 110, and a concentration of the dopant of the emitter region 550 is greater than the concentration of the dopant of the first well 110. The drain region 540 is doped with a conductivity type that is opposite from the conductivity type of the emitter region 550, and the drain region 540 and emitter region 550 form a p-n junction at the upper surface of the semiconductor substrate 102. In some examples, the drain region 540 may be doped with an n-type dopant at a concentration in a range from about 1×10²⁰ cm⁻³ to about 6×10²⁰ cm⁻³, and the emitter region 550 may be doped with a p-type dopant at a concentration in a range from about 1×10²⁰ cm⁻³ to about 2×10²⁰ cm⁻³. Other conductivity type dopants and/or concentrations may be implemented in other examples.

Metal-semiconductor compound 560 is on the upper surface of the semiconductor substrate 102 at the drain region 540 and emitter region 550 together. The metal-semiconductor compound 560 is on both the drain region 540 and emitter region 550 - e.g., extending across the p-n junction between the drain and emitter regions. The metal-semiconductor compound 560 extends laterally from the second isolation structure 126 (or the first gate dielectric layer 122 when the second isolation structure 126 is omitted). The metal-semiconductor compound 560 is like the metal-semiconductor compound 160, 162, 164 (e.g., silicide in some examples). The dielectric layer 170 is further over the metal-semiconductor compound 560. A metal contact 580 extends through the dielectric layer 170 and contacts the metal-semiconductor compound 560. The metal contact 580 is like the metal contact 180. A metal line 590 is over the dielectric layer 170 and over and contacting the metal contact 580. The metal line 590 is like the metal line 190.

As illustrated, the semiconductor device 500 of FIG. 5 includes the source region 142, collector region 152, metal-semiconductor compound 166, metal contact 184, and metal line 194, like in the semiconductor device 100 of FIG. 1. Generally, the semiconductor device 500 of FIG. 5 may be the same as or similar to the semiconductor device 100 of FIG. 1, except, among other things, that the first isolation structure 120 is omitted and the drain region 540 and emitter region 550 are abutted together and shorted by the metal-semiconductor compound 560. In some examples, the first isolation structure 120 may be omitted from the semiconductor devices 200, 300, 400 of FIGS. 2, 3, and 4, and the drain region and emitter region may be abutted together and shorted by a metal-semiconductor compound, like the drain region 540, emitter region 550, and metal-semiconductor compound 560 as shown in FIG. 5.

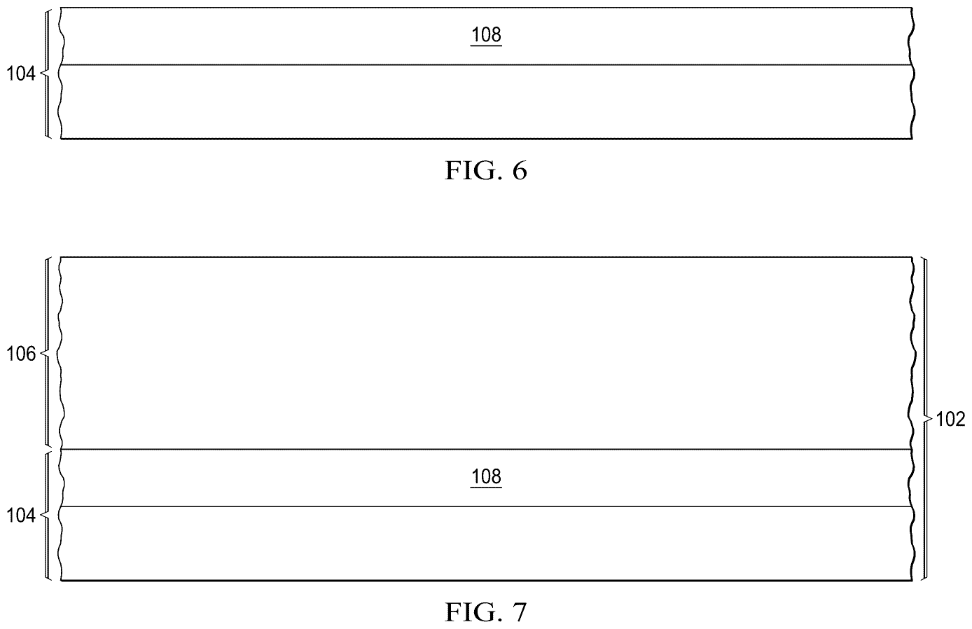

FIGS. 6 through 15 illustrate cross-sectional views of the semiconductor device 100 of FIG. 1 at various stages of manufacturing according to an example method. Modifications to the illustrated method of manufacturing are described below to implement the semiconductor devices 200, 300, 400, 500 of FIGS. 2, 3, 4, and 5 and permutations thereof.

To avoid unnecessary repetition, a buried layer, wells, and doped regions are formed by implanting a dopant into the semiconductor substrate 102. To form a buried layer, a well, or a doped region by implantation, a photoresist may be deposited (e.g., by spin-on) on or over the semiconductor substrate 102 and patterned using photolithography to expose the area corresponding to where the buried layer, well, or doped region is to be formed. Using the patterned photoresist as a mask, an implant is performed to implant the dopant into the semiconductor substrate 102 thereby forming the buried layer, well, or doped region. In some instances, the implantation may be angled. After the implant, the photoresist may be removed, such as by a wet strip or ashing. Examples of dopant types and concentrations of various buried layers, wells, and doped regions described in FIGS. 6 through 15 are as described above.

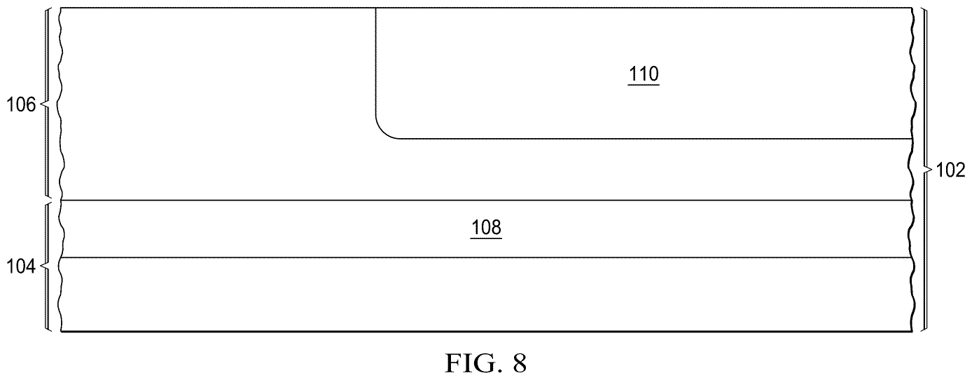

Referring to FIG. 6, a buried layer 108 is formed in a semiconductor support substrate 104. The buried layer 108 may be formed by implanting dopants into the semiconductor support substrate 104. Referring to FIG. 7, an epitaxial layer 106 is formed over the semiconductor support substrate 104. The epitaxial layer 106 may be formed using an appropriate epitaxial growth process, such as low pressure chemical vapor deposition (LPCVD) or the like. The epitaxial layer 106 is doped, such as by in situ doping during the epitaxial growth. The dopant type and concentration of the epitaxial layer 106 are as described above. In the illustrated example, the semiconductor support substrate 104 and the epitaxial layer 106 form a semiconductor substrate 102. In other examples, another semiconductor substrate may be used. For example, the semiconductor substrate 102 may be a bulk silicon wafer (e.g., without the epitaxial layer 106) with the buried layer 108 implanted at a depth in the semiconductor substrate 102.

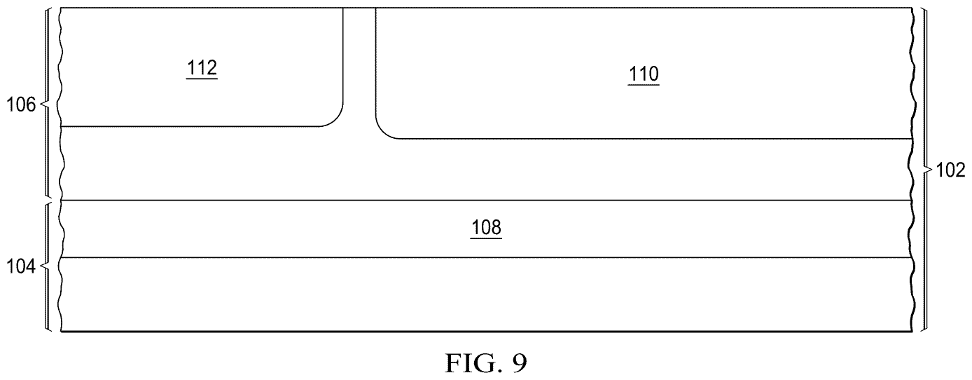

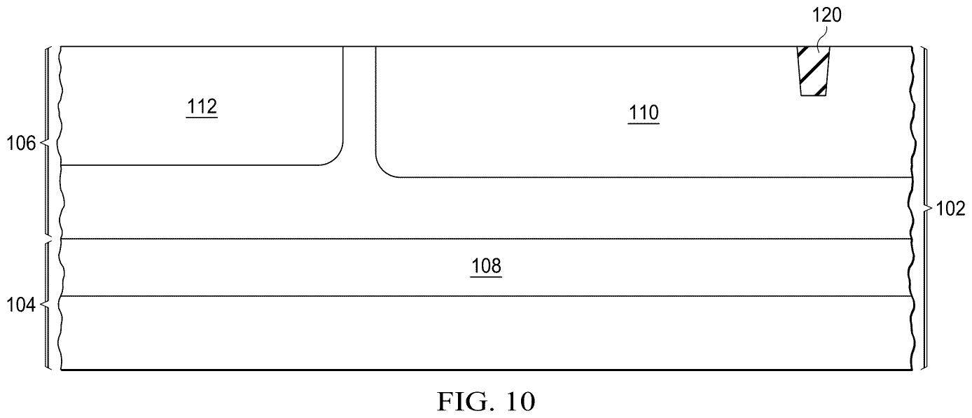

Referring to FIG. 8, a first well 110 is formed in the semiconductor substrate 102. The first well 110 may be formed by implanting dopants into the epitaxial layer 106. The first well 110 may be the first well 410 for manufacturing the semiconductor device 400 of FIG. 4. Referring to FIG. 9, a second well 112 is formed in the semiconductor substrate 102. The second well 112 may be formed by implanting dopants into the epitaxial layer 106. To form the second well 412 of FIG. 4, the photolithography mask may be modified such that the implantation that forms the second well 412 overlaps with the first well 410. An increasing concentration of the second well 412 from the upper surface of the semiconductor substrate 102 causes the surface portion 410a and bulge portion 412a to result. For example, near the upper surface of the semiconductor substrate 102 where the implant overlaps with the first well 410, the concentration of the dopant of the first well 410 is greater than the concentration of the dopant of the second well 412, which results in the surface portion 410a. As the concentration of the second well 412 increases as depth increases, a junction occurs where the concentration of the dopant of the second well 412 becomes greater than the concentration of the dopant of the first well 410, which results in the bulge portion 412a.

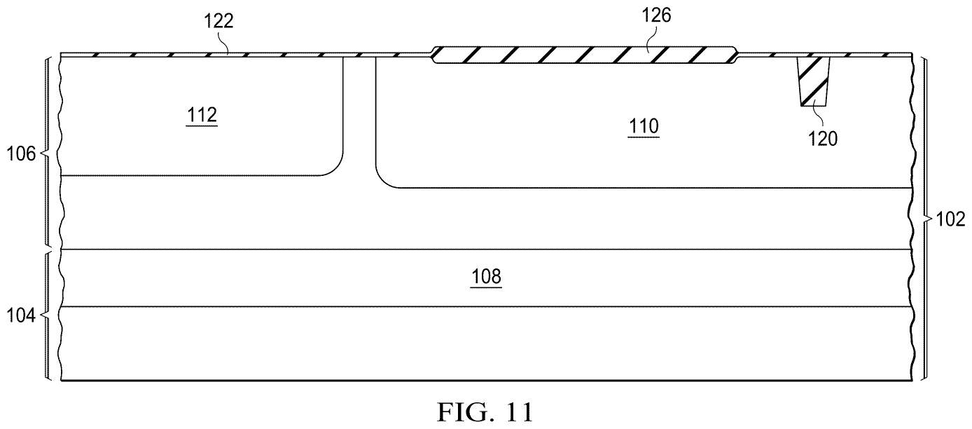

Referring to FIG. 10, a first isolation structure 120 is formed in the semiconductor substrate 102. In the illustrated example, the first isolation structure 120 is an STI structure. The third isolation structure 420 may simultaneously be formed with the first isolation structure 120 for manufacturing the semiconductor device 400 of FIG. 4. To form the first isolation structure 120, a hardmask may be deposited on or over the semiconductor substrate 102 and patterned using appropriate photolithography and etching processes. Using the patterned hardmask, trenches are etched into the semiconductor substrate 102. A dielectric material is deposited in the trenches. For example, a liner layer including a nitride, an oxide, the like, or a combination thereof and be formed or deposited conformally in trenches using in situ steam generation (ISSG) oxidation, atomic layer deposition (ALD), or the like, and a fill isolation material including an oxide may be deposited on the liner layer using high aspect ratio chemical vapor deposition (HAR-CVD), flowable chemical vapor deposition (FCVD), the like, or a combination thereof. Excess dielectric material and the hardmask may be removed, such as by using a chemical mechanical polish (CMP). In other examples, the first isolation structure 120 may be a LOCOS structure, which may be formed as described with respect to and simultaneously with FIG. 11. In some examples, formation of the first isolation structure 120 may be omitted, such as when forming abutting drain and emitter regions like shown in FIG. 5.

Referring to FIG. 11, a first gate dielectric layer 122 and second isolation structure 126 are formed on the semiconductor substrate 102. A pad oxide layer may be formed on the upper surface of the semiconductor substrate 102, and a mask layer may be formed on the pad oxide layer. The pad oxide layer may be formed by an oxidation process, such as thermal oxidation, ISSG oxidation, or the like, and the mask layer may be or include a nitride deposited by chemical vapor deposition (CVD) or the like. The mask layer may then be patterned with an opening corresponding to the location of the second isolation structure 126. The patterning may be by using appropriate photolithography and etch (e.g., reactive ion etch (RIE)) processes. An oxidation process, such as thermal oxidation, ISSG oxidation, or the like, may further oxidize the semiconductor substrate 102 at the opening of the mask layer to form the second isolation structure 126. The mask layer may then be selectively removed, such as by a wet etch selective to the material of the mask layer. In some examples, the pad oxide layer is the first gate dielectric layer 122. In some examples, the pad oxide layer is removed, such as by a wet etch, and the first gate dielectric layer 122 is subsequently formed by an oxidation process or deposition process. In some examples, the mask layer, patterning thereof, and oxidation process through an opening of the patterned mask may be omitted when the second isolation structure 126 is omitted.

To form the semiconductor device 200 of FIG. 2, the mask layer may further be patterned to have an opening corresponding to the location of the third isolation structure 228. The oxidation process that forms the second isolation structure 126 may further oxidize the semiconductor substrate 102 at the respective opening of the mask layer to form the third isolation structure 228.

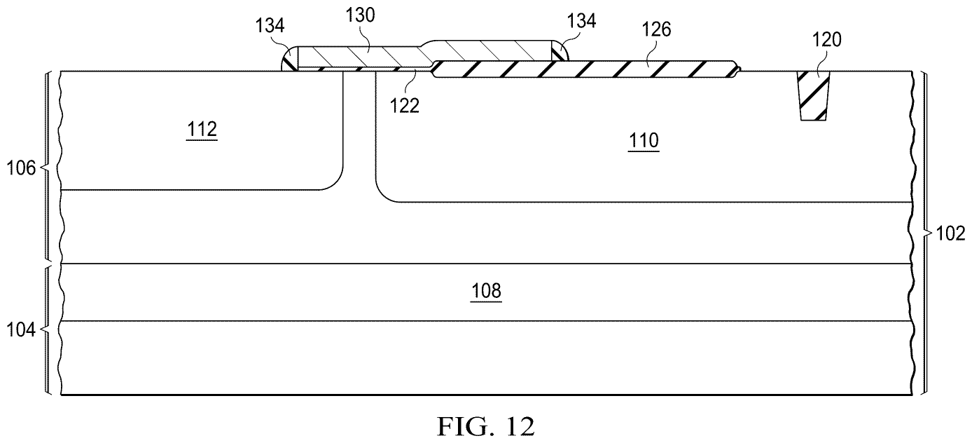

Referring to FIG. 12, a first gate electrode 130 is formed over the first gate dielectric layer 122 and the second isolation structure 126, and first gate spacers 134 are formed on sidewalls of the first gate electrode 130. A material of the first gate electrode 130 may be deposited over the semiconductor substrate 102 by any appropriate deposition process, such as CVD, physical vapor deposition (PVD), or the like. In some examples, such as when the first gate electrode 130 is or includes doped polysilicon, the polysilicon may be in situ doped and/or doped by implantation. The material of the first gate electrode 130 is then patterned into the first gate electrode 130 using appropriate photolithography and etching processes. Patterning the first gate electrode 130 further patterns the first gate dielectric layer 122. A conformal dielectric layer is conformally formed on or over sidewall and upper surfaces of the first gate electrode 130, such as using an appropriate deposition process like CVD or ALD. The conformal dielectric layer is anisotropically etched, such as by RIE, which results in the first gate spacers 134.

To form the semiconductor device 300 of FIG. 3, the material of the first gate electrode 130 may also be patterned into the second gate electrode 332 while the first gate electrode 130 is patterned, and the first gate dielectric layer 122 under the second gate electrode 332 may also be patterned into the second gate dielectric layer 324 while the first gate dielectric layer 122 is patterned. Further, anisotropically etching the conformal dielectric layer from which the first gate spacers 134 are formed further forms the second gate spacers 336.

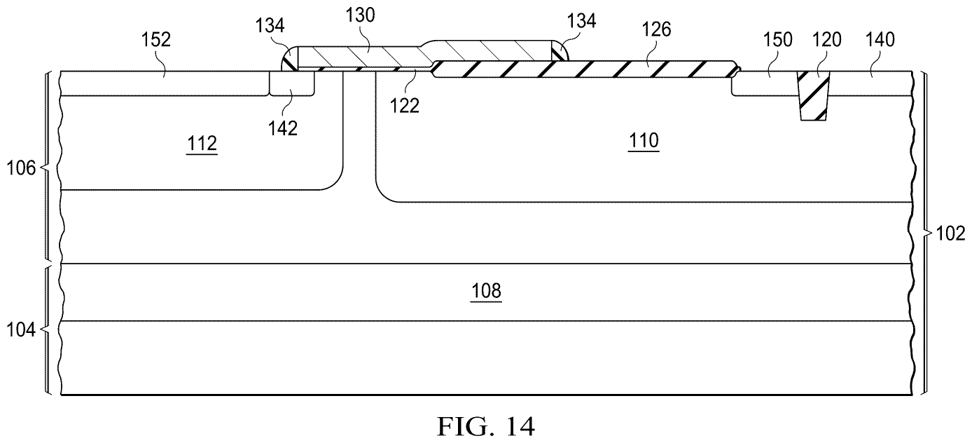

Referring to FIG. 13, a drain region 140 and a source region 142 are formed in the semiconductor substrate 102. The drain region 140 and source region 142 may be formed by implanting dopants into the epitaxial layer 106. Referring to FIG. 14, an emitter region 150 and a collector region 152 are formed in the semiconductor substrate 102. The emitter region 150 and a collector region 152 may be formed by implanting dopants into the epitaxial layer 106. To form the semiconductor devices 200, 300, 400 of FIGS. 2, 3, and 4, the photolithography masks may be modified for the respective implantations to achieve the drain region 140, source region 242, 342, 442, emitter region 150, and collector region 252, 352, 452.

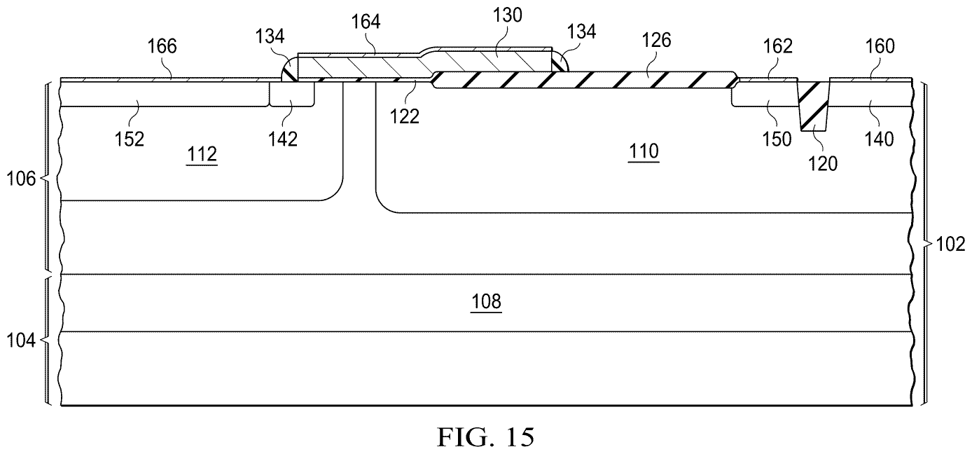

Referring to FIG. 15, metal-semiconductor compound 160, 162, 164, 166 are formed. A metal (e.g., Ni, Ti, Co, Pt) may be deposited, such as by PVD, CVD, or the like, over the semiconductor substrate 102. The metal is reacted with a semiconductor material, such as the semiconductor material of the semiconductor substrate 102 and, if, e.g., polysilicon, the material of the first gate electrode 130. An anneal process may be used to cause the metal to react with a semiconductor material. Any unreacted metal may be removed, such as by an etch selective to the metal. To form the semiconductor devices 200, 300, 400 of FIGS. 2, 3, and 4, metal-semiconductor compound 266, 268, 366, 368, 369, 466, 468 may be formed by the processing described with respect to FIG. 15.

Referring to FIG. 1, a dielectric layer 170 is formed over the semiconductor substrate 102. The dielectric layer 170 may include one or multiple dielectric layers formed of any appropriate dielectric material and deposited by any appropriate deposition process, such as CVD, PVD, or the like. Metal contacts 180, 182, 184 are formed through the dielectric layer 170, and metal lines 190, 192, 194 are formed over the dielectric layer 170 and over and on the metal contacts 180, 182, 184, respectively. To form the metal contacts, openings are formed through the dielectric layer 170 using photolithography and etching processes. Respective openings expose respective metal-semiconductor compound 160, 162, 166, or metal-semiconductor compound 160, 162, 266, 268, 366, 368, 466, 468 for forming the semiconductor devices 200, 300, 400 of FIGS. 2, 3, and 4. A barrier and/or adhesion layer may then be conformally deposited, such as by CVD, ALD, or the like, in the openings and over the dielectric layer 170, and a fill metal may be deposited, such as by CVD, PVD, or the like, on the barrier and/or adhesion layer. The barrier and/or adhesion layer and fill metal in the openings form the metal contacts 180, 182, 184 or metal contacts 180, 182, 284, 286. The barrier and/or adhesion layer and fill metal over the dielectric layer 170 may be patterned into the metal lines 190, 192, 194 or metal lines 190, 192, 294, 296, such as by appropriate photolithography and etching processes.

Although various examples have been described in detail, it should be understood that various changes, substitutions, and alterations can be made therein without departing from the scope defined by the appended claims.

What is claimed is:

1. A semiconductor device, comprising:
a semiconductor substrate;
a first well in the semiconductor substrate, the first well being doped with a first conductivity type;
a second well in the semiconductor substrate, the second well being doped with a second conductivity type opposite from the first conductivity type;
a gate electrode over the semiconductor substrate, the gate electrode extending laterally over the first well and the second well;
a source region in the second well, the source region being doped with the first conductivity type;
a collector region in the second well, the collector region being doped with the second conductivity type;
an emitter region in the first well, the emitter region being doped with the second conductivity type;
a drain region in the first well, the drain region being doped with the first conductivity type, the gate electrode being laterally between the source region and the emitter region; and
a silicide on the source region and the collector region.

2. The semiconductor device of claim 1, wherein the source region and the collector region forming a p-n junction at an upper surface of the semiconductor substrate.

3. The semiconductor device of claim 1, wherein no isolation structure including an isolation material is in the semiconductor substrate laterally between the source region and the collector region.

4. The semiconductor device of claim 1, wherein:
the emitter region is laterally between the drain region and the gate electrode; and
the source region is laterally between the collector region and the gate electrode.

5. The semiconductor device of claim 4, further comprising an isolation structure in the semiconductor substrate, the isolation structure being laterally between the drain region and the emitter region.

6. The semiconductor device of claim 5, wherein the isolation structure is a shallow trench isolation (STI) structure.

7. The semiconductor device of claim 1, further comprising:
an isolation structure on the semiconductor substrate, wherein the isolation structure includes a local oxidation of semiconductor (LOCOS) structure, a shallow trench isolation (STI) structure, or a combination thereof; and
a gate dielectric layer on the semiconductor substrate and extending from the isolation structure, wherein the gate dielectric layer and the isolation structure are laterally between the source region and the emitter region, and the gate electrode is over the gate dielectric layer and the isolation structure.

8. The semiconductor device of claim 1, wherein the first well includes a surface portion at an upper surface of the semiconductor substrate, the surface portion of the first well being below the gate electrode and over a bulge portion of the second well.

9. A semiconductor device, comprising:
a semiconductor substrate;
a first well in the semiconductor substrate, the first well being doped with a first conductivity type;
a second well in the semiconductor substrate, the second well being doped with a second conductivity type opposite from the first conductivity type;
a gate electrode over the semiconductor substrate, the gate electrode extending laterally over the first well and the second well;
a source region in the second well, the source region being doped with the first conductivity type, the source region forming a p-n junction with the second well, the p-n junction being at a first depth from an upper surface of the semiconductor substrate;
a collector region in the second well, the collector region being doped with the second conductivity type;
an isolation structure on the semiconductor substrate and laterally between the source region and the collector region, a bottom surface of the isolation structure being at a second depth from the upper surface of the semiconductor substrate, the first depth being at least 130% of the second depth;
an emitter region in the first well, the emitter region being doped with the second conductivity type; and
a drain region in the first well, the drain region being doped with the first conductivity type, the gate electrode being laterally between the source region and the emitter region.

10. The semiconductor device of claim 9, wherein the first depth is deeper than the second depth.

11. The semiconductor device of claim 9, wherein the isolation structure is a local oxidation of semiconductor (LOCOS) structure.

12. The semiconductor device of claim 9, further comprising a shallow trench isolation (STI) structure in the semiconductor substrate, the STI structure being laterally between the emitter region and the drain region, a bottom surface of the STI structure being at a third depth from the upper surface of the semiconductor substrate, the third depth being a greater depth than the second depth.

13. The semiconductor device of claim 9, further comprising a silicide on the emitter region and the drain region.

14. The semiconductor device of claim 9, wherein the first well includes a surface portion at the upper surface of the semiconductor substrate, the surface portion of the first well being below the gate electrode and over a bulge portion of the second well.

15. A semiconductor device, comprising:
a semiconductor substrate;
a first well in the semiconductor substrate, the first well being doped with a first conductivity type;
a second well in the semiconductor substrate, the second well being doped with a second conductivity type opposite from the first conductivity type;
a first gate electrode over the semiconductor substrate, the first gate electrode extending laterally over the first well and the second well;
a source region in the second well, the source region being doped with the first conductivity type;
a collector region in the second well, the collector region being doped with the second conductivity type;
a second gate electrode over the semiconductor substrate, the second gate electrode being laterally between the source region and the collector region;
an emitter region in the first well, the emitter region being doped with the second conductivity type; and
a drain region in the first well, the drain region being doped with the first conductivity type, the first gate electrode being laterally between the source region and the emitter region.

16. The semiconductor device of claim 15, wherein the second gate electrode is electrically connected to the collector region.

17. The semiconductor device of claim 15, wherein the first gate electrode includes polycrystalline silicon, and the second gate electrode includes polycrystalline silicon.

18. The semiconductor device of claim 15, further comprising:
a first gate oxide layer on an upper surface of the semiconductor substrate, the first gate electrode being over the first gate oxide layer; and
a second gate oxide layer on the upper surface of the semiconductor substrate, the second gate electrode being over the second gate oxide layer.

19. The semiconductor device of claim 15, wherein the first well includes a surface portion at an upper surface of the semiconductor substrate, the surface portion of the first well being below the first gate electrode and over a bulge portion of the second well.

20. A semiconductor device, comprising:
a semiconductor substrate;
a first well in the semiconductor substrate, the first well being doped with a first conductivity type;
a second well in the semiconductor substrate, the second well being doped with a second conductivity type opposite from the first conductivity type;
a gate electrode over the semiconductor substrate, the gate electrode extending laterally over the first well and the second well, wherein the first well includes a surface portion at an upper surface of the semiconductor substrate, the surface portion of the first well being below the gate electrode and over a bulge portion of the second well;
a source region in the second well, the source region being doped with the first conductivity type;
a collector region in the second well, the collector region being doped with the second conductivity type;
an emitter region in the first well, the emitter region being doped with the second conductivity type; and
a drain region in the first well, the drain region being doped with the first conductivity type, the gate electrode being laterally between the source region and the emitter region.

21. The semiconductor device of claim 20, wherein a p-n junction is formed by the surface portion and the bulge portion.
